(19) United States
(12) Patent Application Publication
(10) Pub. No.: US 2026/0198065 A1
(43) Pub. Date: Jul. 9, 2026

(54) SEMICONDUCTOR DEVICE

(71) Applicant: Mitsubishi Electric Corporation, Tokyo (JP)

(72) Inventors: Masaomi MIYAZAWA, Tokyo (JP); Ren KUGA, Tokyo (JP)

(73) Assignee: Mitsubishi Electric Corporation, Tokyo (JP)

(21) Appl. No.: 19/422,109

(22) Filed: Dec. 16, 2025

(30) Foreign Application Priority Data
Jan. 6, 2025 (JP) 2025-001724

(51) Int. Cl. H10D 80/20; H10W 40/25; H10W 76/15; H10W 90/00; H10W 90/10

(52) U.S. Cl. CPC H10D 80/20; H10W 40/255; H10W 76/15; H10W 90/10; H10W 90/753; H10W 90/754

(57) ABSTRACT

A semiconductor device includes a bidirectional switching circuit including a substrate, a first switching element, a second switching element, a first rectifying element, and a second rectifying element. The substrate includes a first circuit pattern electrically connected to a gate electrode of the first switching element, a second circuit pattern electrically connected to a gate electrode of the second switching element, a third circuit pattern electrically connected to a negative electrode of the first switching element, and a fourth circuit pattern electrically connected to a negative electrode of the second switching element. When viewed from the first direction, the third circuit pattern is arranged adjacently to the first circuit pattern and the fourth circuit pattern is arranged adjacently to the second circuit pattern.

### CROSS REFERENCE TO RELATED APPLICATIONS

This nonprovisional application is based on Japanese Patent Application No. 2025-001724 filed with the Japan Patent Office on Jan. 6, 2025, the entire contents of which are hereby incorporated by reference.

### BACKGROUND OF THE INVENTION

### Field of the Invention

The present disclosure relates to a semiconductor device.

### Description of the Background Art

Japanese Patent Laying-Open No. 2024-13924 discloses a semiconductor module including a first unit to implement an upper arm of an inverter and a second unit to implement a lower arm of the inverter. In the semiconductor module in Japanese Patent Laying-Open No. 2024-13924, control conductor patterns of the first unit and the second unit are in point symmetry to each other.

In the semiconductor module in Japanese Patent Laying-Open No. 2024-13924, a power collecting portion of the first unit and each conductive pattern of the second unit are electrically connected to each other, and a first connecting line that forms a main current path extends over controlling conductive patterns of the first unit and the second unit.

### SUMMARY OF THE INVENTION

A semiconductor device according to the present disclosure includes a bidirectional switching circuit. The bidirectional switching circuit includes a substrate having a first surface and a first switching element, a second switching element, a first rectifying element, and a second rectifying element that are mounted on the first surface. The first rectifying element is connected in anti-parallel to the first switching element. The second rectifying element is connected in anti-parallel to the second switching element. Each of the first switching element and the second switching element includes a positive electrode, a negative electrode, and a gate electrode. The substrate includes a first circuit pattern electrically connected to the gate electrode of the first switching element, a second circuit pattern electrically connected to the gate electrode of the second switching element, a third circuit pattern electrically connected to the negative electrode of the first switching element, and a fourth circuit pattern electrically connected to the negative electrode of the second switching element. When viewed from a first direction orthogonal to the first surface, the gate electrode of the first switching element and the first circuit pattern are in line symmetry to the gate electrode of the second switching element and the second circuit pattern. When viewed from the first direction, the third circuit pattern is arranged adjacently to the first circuit pattern and the fourth circuit pattern is arranged adjacently to the second circuit pattern.

The foregoing and other objects, features, aspects and advantages of this invention will become more apparent from the following detailed description of this invention when taken in conjunction with the accompanying drawings.

### BRIEF DESCRIPTION OF THE DRAWINGS

FIG. 1 is a perspective view showing an exemplary semiconductor device according to a first embodiment.

FIG. 2 is a circuit diagram showing an exemplary bidirectional switching circuit of the semiconductor device according to the first embodiment.

FIG. 3 is a plan view showing an exemplary layout of first to fourth circuit patterns in the semiconductor device according to the first embodiment.

FIG. 4 is a cross-sectional view along an arrow IV-IV in FIG. 3.

FIG. 5 is a plan view showing an exemplary layout of first and third signal terminals in the semiconductor device according to the first embodiment.

FIG. 6 is a cross-sectional view along an arrow VI-VI in FIG. 5.

FIG. 7 is a diagram for illustrating a path of a main current in the bidirectional switching circuit shown in FIG. 2.

FIG. 8 is a plan view showing an exemplary layout of first to fourth circuit patterns in a semiconductor device according to a second embodiment.

FIG. 9 is a circuit diagram showing an exemplary bidirectional switching circuit of the semiconductor device according to the second embodiment.

FIG. 10 is a perspective view showing an exemplary semiconductor device according to a third embodiment.

FIG. 11 is a circuit diagram showing an exemplary bidirectional switching circuit of the semiconductor device according to the third embodiment.

FIG. 12 is a plan view showing an exemplary layout of first to fourth circuit patterns in the semiconductor device according to the third embodiment.

### DESCRIPTION OF THE PREFERRED EMBODIMENTS

An embodiment of the present disclosure will be described below with reference to the drawings. The same or corresponding elements below have the same reference characters allotted and redundant description will not be repeated.

### First Embodiment

### Configuration of Semiconductor Device

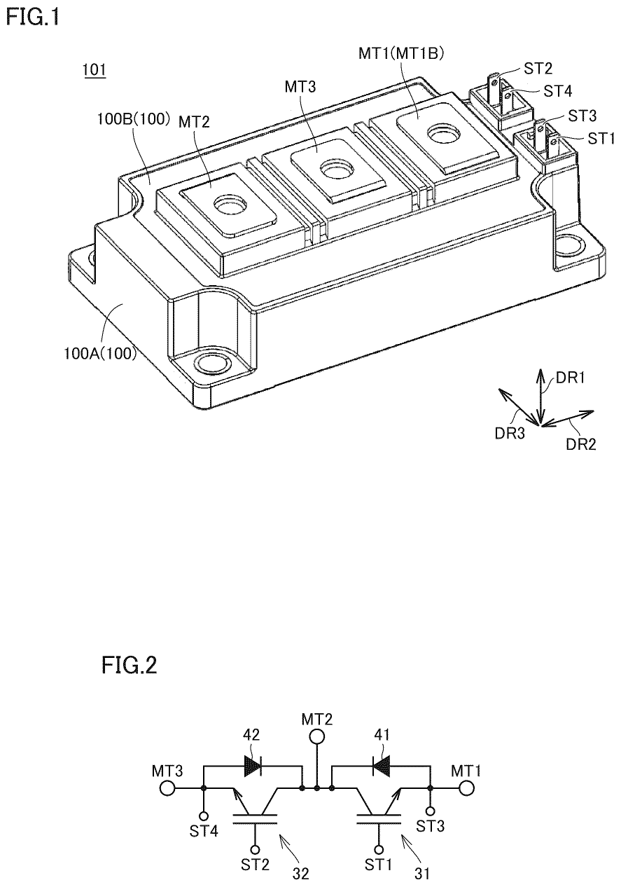

A configuration of a semiconductor device 101 according to a first embodiment will be described with reference to FIGS. 1 to 6. Semiconductor device 101 shown in FIG. 1 is a module including a bidirectional switching circuit shown in FIG. 2. As shown in FIG. 1, semiconductor device 101 includes a casing 100. Such a component as a switching element included in the bidirectional switching circuit is accommodated in casing 100. Casing 100 includes, for example, a frame portion 100A and a lid portion 100B.

Semiconductor device 101 further includes main terminals MT1, MT2, and MT3 and signal terminals ST1, ST2, ST3, and ST4. Main terminals MT1, MT2, and MT3 and signal terminals ST1, ST2, ST3, and ST4 each have a portion exposed to the outside of casing 100, and are electrically connectable to external equipment. Main terminals MT1, MT2, and MT3 and signal terminals ST1, ST2, ST3, and ST4 each have, for example, a portion that projects from an end portion (lid portion) 100B in a first direction DR1 of casing 100 to the outside. Main terminal MT1 is electrically connected to an output terminal from which alternating-current (AC) output of the semiconductor device is taken out, the semiconductor device implementing upper and lower arms of a not-shown three-level inverter. Main terminal MT3 is electrically connected to an intermediate potential terminal of a not-shown direct-current (DC) power supply (for example, a DC stabilized power supply, a fuel cell, a rechargeable battery, a solar power generator, or the like).

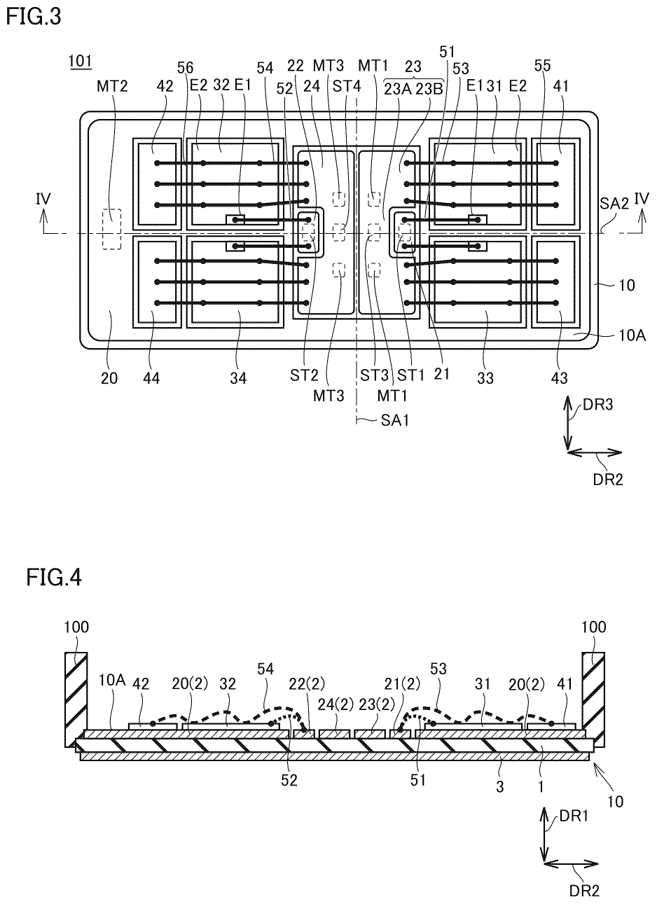

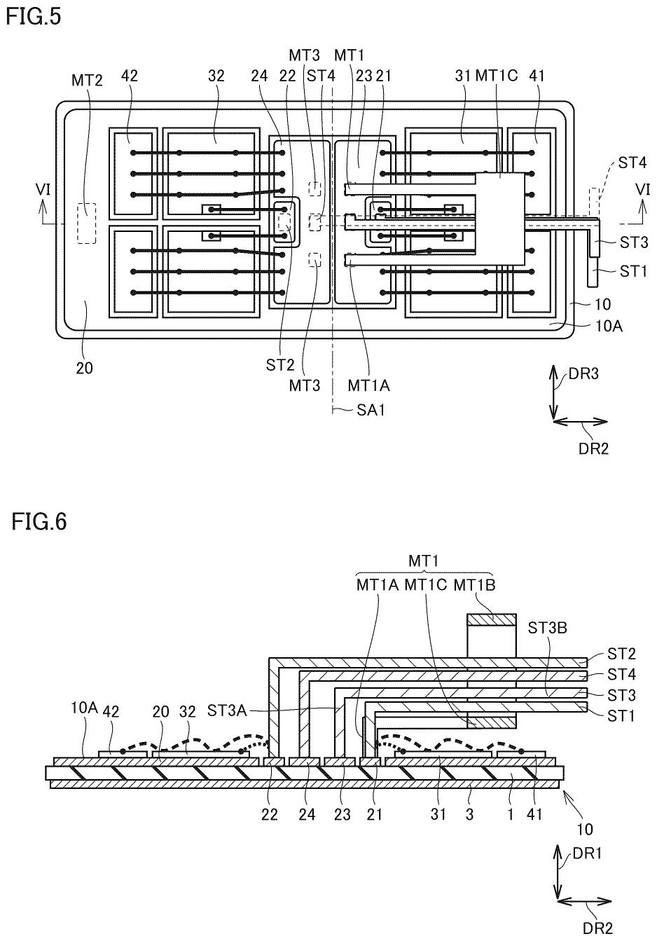

For the sake of convenience of description, FIG. 3 does not show main terminals MT1, MT2, and MT3, signal terminals ST1, ST2, ST3, and ST4, and casing 100. FIG. 4 does not show main terminals MT1, MT2, and MT3 and signal terminals ST1, ST2, ST3, and ST4 as well as lid portion 100B of casing 100. FIG. 5 does not show a part of main terminal MT1 as well as main terminals MT2 and MT3, signal terminal ST2, and casing 100. FIG. 6 does not show main terminals MT2 and MT3 and casing 100.

As shown in FIG. 2, the bidirectional switching circuit included in semiconductor device 101 includes a first switching element 31, a second switching element 32, a first rectifying element 41, and a second rectifying element 42.

First switching element 31 and second switching element 32 are each, for example, an insulated gate bipolar transistor (IGBT) or a metal oxide semiconductor field effect transistor (MOSFET). Each of first rectifying element 41 and second rectifying element 42 is, for example, a Schottky barrier diode

### (sbd) or a Pn Junction Diode (pnd).

A semiconductor material contained in each switching element and each rectifying element is not particularly restricted. Such a semiconductor material may be silicon (Si). The semiconductor material may be a wide bandgap semiconductor such as silicon carbide (SiC), gallium nitride (GaN), or diamond. In an example where the semiconductor material contained in each switching element and each rectifying element is the wide bandgap semiconductor, a stable operation at a high temperature and a high voltage can be performed and a switching speed can be increased.

Each of first switching element 31 and second switching element 32 has a gate electrode E1 (see FIG. 3), a negative electrode E2 (see FIG. 3), and a positive electrode (not shown). In an example where first switching element 31 and second switching element 32 are each an IGBT, the negative electrode is an emitter electrode and the positive electrode is a collector electrode. In an example where first switching element 31 and second switching element 32 are each a MOSFET, the negative electrode is a source electrode and the positive electrode is a drain electrode.

First rectifying element 41 is connected in anti-parallel to first switching element 31. Second rectifying element 42 is connected in anti-parallel to second switching element 32. A forward direction of first rectifying element 41 and a forward direction of second rectifying element 42 are reverse to each other.

First switching element 31 and first rectifying element 41 are electrically connected between main terminal MT1 and main terminal MT2. Second switching element 32 and second rectifying element 42 are electrically connected between main terminal MT2 and main terminal MT3.

Gate electrode E1 of first switching element 31 is electrically connected to signal terminal ST1. Gate electrode E1 of first switching element 31 is equal in potential to signal terminal ST1. Gate electrode E1 of second switching element 32 is electrically connected to signal terminal ST2. Gate electrode E1 of second switching element 32 is equal in potential to signal terminal ST2.

Negative electrode E2 of first switching element 31 is electrically connected to main terminal MT1 and signal terminal ST3. Negative electrode E2 of first switching element 31 is equal in potential to signal terminal ST3. Negative electrode E2 of second switching element 32 is electrically connected to main terminal MT3 and signal terminal ST4. Negative electrode E2 of second switching element 32 is equal in potential to signal terminal ST4.

The positive electrode of first switching element 31 and the positive electrode of second switching element 32 are electrically connected to main terminal MT2.

In the bidirectional switching circuit of semiconductor device 101, a first current path leading to main terminal MT1, first rectifying element 41, second switching element 32, and main terminal MT3 or a second current path leading to main terminal MT3, second rectifying element 42, first switching element 31, and main terminal MT1 may be formed. In the bidirectional switching circuit, a bidirectional current path may be formed between main terminal MT1 and main terminal MT3.

First switching element 31 and first rectifying element 41 may configured as being integrated as a reverse-conducting (RC) IGBT chip. Similarly, second switching element 32 and second rectifying element 42 may configured as being integrated as an RC-IGBT chip.

As shown in FIGS. 3 and 4, semiconductor device 101 further includes a substrate 10. Substrate 10 has a first surface 10A. A direction orthogonal to first surface 10A is denoted as first direction DR1 below, and two directions along first surface 10A which are orthogonal to each other are denoted as a second direction DR2 and a third direction DR3, respectively. First switching element 31, second switching element 32, first rectifying element 41, and second rectifying element 42 are mounted on first surface 10A of substrate 10. First surface 10A of substrate 10 is arranged inside casing 100.

Substrate 10 includes an insulating layer 1 and a conductor layer 2 arranged on insulating layer 1. Conductor layer 2 includes a plurality of circuit patterns arranged at a distance from one another on insulating layer 1.

Conductor layer 2 includes a first circuit pattern 21 electrically connected to gate electrode E1 of first switching element 31, a second circuit pattern 22 electrically connected to gate electrode E1 of second switching element 32, a third circuit pattern 23 electrically connected to negative electrode E2 of first switching element 31, and a fourth circuit pattern 24 electrically connected to negative electrode E2 of second switching element 32.

Gate electrode E1 of first switching element 31 is electrically connected to first circuit pattern 21, for example, through a wiring member 51 such as a bonding wire. Gate electrode E1 of second switching element 32 is electrically connected to second circuit pattern 22, for example, through a wiring member 52 such as a bonding wire. Negative electrode E2 of first switching element 31 is electrically connected to third circuit pattern 23, for example, through a wiring member 53 such as a bonding wire. Negative electrode E2 of second switching element 32 is electrically connected to fourth circuit pattern 24, for example, through a wiring member 54 such as a bonding wire. The positive electrode of each of first switching element 31 and second switching element 32 is electrically connected to circuit pattern 20. The wiring member is not limited to the bonding wire and may be any wiring member such as a ribbon or a lead.

As shown in FIG. 3, when viewed from first direction DR1, gate electrode E1 of first switching element 31 and first circuit pattern 21 are in line symmetry to gate electrode E1 of second switching element 32 and second circuit pattern 22. When viewed from first direction DR1, first switching element 31, first circuit pattern 21, third circuit pattern 23, fourth circuit pattern 24, second circuit pattern 22, and second switching element 32 are arranged as being aligned sequentially in second direction DR2. A symmetry axis SA1 of line symmetry extends along third direction DR3 which extends along first surface 10A and is orthogonal to second direction DR2. When viewed from first direction DR1, gate electrode E1 of first switching element 31, first circuit pattern 21, third circuit pattern 23, fourth circuit pattern 24, second circuit pattern 22, and gate electrode E1 of second switching element 32 are arranged as being aligned sequentially in second direction DR2.

As shown in FIG. 3, when viewed from first direction DR1, third circuit pattern 23 is arranged adjacently to first circuit pattern 21. Fourth circuit pattern 24 is arranged adjacently to second circuit pattern 22.

From a different point of view, when viewed from first direction DR1, first circuit pattern 21 is arranged in proximity to third circuit pattern 23. An interval between first circuit pattern 21 and third circuit pattern 23 may be shortest among intervals between first circuit pattern 21 and other circuit patterns of the plurality of circuit patterns. The interval between first circuit pattern 21 and third circuit pattern 23 is, for example, not longer than an interval between first circuit pattern 21 and circuit pattern 20. When viewed from first direction DR1, second circuit pattern 22 is arranged in proximity to fourth circuit pattern 24. An interval between second circuit pattern 22 and fourth circuit pattern 24 may be shortest among intervals between second circuit pattern 22 and other circuit patterns of the plurality of circuit patterns. The interval between second circuit pattern 22 and fourth circuit pattern 24 is, for example, not longer than an interval between second circuit pattern 22 and circuit pattern 20.

Preferably, when viewed from first direction DR1, third circuit pattern 23 includes a first portion 23A and a pair of second portions 23B. First portion 23A is arranged opposite to first switching element 31 with respect to first circuit pattern 21. The pair of second portions 23B extends from first portion 23A toward first switching element 31 and is arranged as being opposed to each other such that at least a part of first circuit pattern 21 lies therebetween. The pair of second portions 23B extends outward from opposing ends of first portion 23A in third direction DR3 and projects toward first switching element 31 relative to first portion 23A in second direction DR2. When viewed from first direction DR1, third circuit pattern 23 is in a U shape. When viewed from first direction DR1, third circuit pattern 23 is provided with a recess. First circuit pattern 21 is arranged in the recess in third circuit pattern 23. When viewed from first direction DR1, third circuit pattern 23 is provided to surround first circuit pattern 21 from three sides which are a side opposite to first switching element 31 in second direction DR2 and one side and the other side of third direction DR3.

One ends of wiring members 53 through which negative electrode E2 of first switching element 31 and third circuit pattern 23 are electrically connected to each other are joined, for example, to the pair of second portions 23B.

The pair of second portions 23B of third circuit pattern 23 is arranged as being opposed to each other, for example, such that the entire first circuit pattern 21 lies therebetween in third direction DR3. An end of third circuit pattern 23 located on a side of first switching element 31 in second direction DR2 and an end of first circuit pattern 21 located on the side of first switching element 31 in second direction DR2 are arranged at a distance from each other on the same straight line extending along third direction DR3.

Fourth circuit pattern 24 is in line symmetry to third circuit pattern 23. Fourth circuit pattern 24 includes a first portion and a pair of second portions. The first portion of fourth circuit pattern 24 is arranged opposite to second switching element 32 with respect to second circuit pattern 22. The pair of second portions of fourth circuit pattern 24 extends from the first portion toward second switching element 32 and is arranged as being opposed to each other such that at least a part of second circuit pattern 22 lies therebetween. In fourth circuit pattern 24, the pair of second portions extends outward from opposing ends of the first portion in third direction DR3 and projects toward second switching element 32 relative to the first portion in second direction DR2. When viewed from first direction DR1, fourth circuit pattern 24 is in a U shape. When viewed from first direction DR1, fourth circuit pattern 24 is provided with a recess. Second circuit pattern 22 is arranged in the recess in fourth circuit pattern 24. When viewed from first direction DR1, fourth circuit pattern 24 is provided to surround second circuit pattern 22 from three sides which are a side opposite to second switching element 32 in second direction DR2 and one side and the other side in third direction DR3.

One ends of wiring members 54 through which negative electrode E2 of second switching element 32 and fourth circuit pattern 24 are electrically connected to each other are joined, for example, to the pair of second portions of fourth circuit pattern 24.

The pair of second portions of fourth circuit pattern 24 is arranged as being opposed to each other, for example, such that the entire second circuit pattern 22 lies therebetween in third direction DR3. An end of fourth circuit pattern 24 located on a side of second switching element 32 in second direction DR2 and an end of second circuit pattern 22 located on the side of second switching element 32 in second direction DR2 are arranged at a distance from each other on the same straight line that extends along third direction DR3.

Preferably, when viewed from first direction DR1, third circuit pattern 23 is in line symmetry to fourth circuit pattern 24. More preferably, third circuit pattern 23 is in line symmetry to fourth circuit pattern 24 with respect to symmetry axis SA1.

Preferably, when viewed from first direction DR1, wiring member 51 through which gate electrode E1 of first switching element 31 and first circuit pattern 21 are electrically connected to each other is in line symmetry to wiring member 52 through which gate electrode E1 of second switching element 32 and second circuit pattern 22 are electrically connected to each other. More preferably, wiring member 51 is in line symmetry to wiring member 52 with respect to symmetry axis SA1.

Preferably, when viewed from first direction DR1, wiring member 53 through which negative electrode E2 of first switching element 31 and third circuit pattern 23 are electrically connected to each other is in line symmetry to wiring member 54 through which negative electrode E2 of second switching element 32 and fourth circuit pattern 24 are electrically connected to each other. More preferably, wiring member 53 is in line symmetry to wiring member 54 with respect to symmetry axis SA1.

More preferably, when viewed from first direction DR1, first rectifying element 41 is in line symmetry to second rectifying element 42. More preferably, when viewed from first direction DR1, first rectifying element 41 is in line symmetry to second rectifying element 42 with respect to symmetry axis SA1.

More preferably, when viewed from first direction DR1, a wiring member 55 through which negative electrode E2 of first switching element 31 and first rectifying element 41 are electrically connected to each other is in line symmetry to a wiring member 56 through which negative electrode E2 of second switching element 32 and second rectifying element 42 are electrically connected to each other. More preferably, wiring member 55 is in line symmetry to wiring member 56 with respect to symmetry axis SA1.

Wiring member 51 through which gate electrode E1 of first switching element 31 and first circuit pattern 21 are electrically connected to each other is arranged not to intersect with wiring member 53 through which negative electrode E2 of first switching element 31 and third circuit pattern 23 are electrically connected to each other. Wiring member 51 and wiring member 53 extend along second direction DR2. Preferably, wiring member 51 is arranged substantially in parallel to wiring member 53.

Wiring member 52 through which gate electrode E1 of second switching element 32 and second circuit pattern 22 are electrically connected to each other is arranged not to intersect with wiring member 54 through which negative electrode E2 of second switching element 32 and fourth circuit pattern 24 are electrically connected to each other. Wiring member 52 and wiring member 54 extend along second direction DR2. Preferably, wiring member 52 is arranged substantially in parallel to wiring member 54.

A material for insulating layer 1 may be any electrically insulating material, and includes, for example, at least one selected from the group consisting of a ceramic material such as aluminum nitride (AlN) or aluminum oxide (Al₂O₃) and a resin material such as polyimide. A material for conductor layer 2 includes, for example, at least one selected from the group consisting of copper (Cu), aluminum (Al), and gold (Au). A material for the wiring member includes, for example, at least one selected from the group consisting of copper (Cu), aluminum (Al), and gold (Au).

Substrate 10 may further include a heat radiation layer 3. Heat radiation layer 3 is arranged opposite to conductor layer 2 with respect to insulating layer 1. Heat radiation layer 3 may be exposed at casing 100. A material for heat radiation layer 3 may be any material higher in thermal conductivity than insulating layer 1, and includes, for example, a metallic material and preferably includes at least one selected from the group consisting of Cu and Al.

FIG. 3 shows with a dashed line, a region electrically connected to the main terminal or the signal terminal in each circuit pattern of conductor layer 2. First circuit pattern 21 includes a first connection region electrically connected to signal terminal ST1. Second circuit pattern 22 includes a second connection region electrically connected to signal terminal ST2. Third circuit pattern 23 includes a third connection region electrically connected to signal terminal ST3. The third connection region is included in first portion 23A of third circuit pattern 23. Fourth circuit pattern 24 includes a fourth connection region electrically connected to signal terminal ST4. The fourth connection region is included in the first portion of fourth circuit pattern 24.

Third circuit pattern 23 further includes at least one fifth connection region electrically connected to main terminal MT1. The at least one fifth connection region is included in the pair of second portions 23B of third circuit pattern 23. Preferably, third circuit pattern 23 includes a plurality of fifth connection regions included in the pair of second portions 23B, respectively. From a different point of view, main terminal MT1 preferably includes a plurality of first internal connection portions MT1A (see FIGS. 5 and 6) connected to third circuit pattern 23. Fourth circuit pattern 24 further includes at least one sixth connection region electrically connected to main terminal MT3. The at least one sixth connection region is included in the pair of second portions of fourth circuit pattern 24. Preferably, fourth circuit pattern 24 includes a plurality of sixth connection regions included in the pair of second portions, respectively. From a different point of view, main terminal MT3 preferably includes a plurality of internal connection portions (not shown) connected to fourth circuit pattern 24. Circuit pattern 20 includes a seventh connection region electrically connected to main terminal MT2.

The first connection region, the third connection region, the fourth connection region, and the second connection region are arranged as being aligned in second direction DR2. The fifth connection region and the sixth connection region are not arranged as being aligned with each of the first connection region, the third connection region, the fourth connection region, and the second connection region and first circuit pattern 21 and second circuit pattern 22 in second direction DR2. The fifth connection region and the sixth connection region are arranged at a distance from each of the first connection region, the third connection region, the fourth connection region, and the second connection region in third direction DR3. The fifth connection region and the sixth connection region are in line symmetry to each other with respect to symmetry axis SA1.

As shown in FIG. 3, semiconductor device 101 may further include a third switching element 33, a fourth switching element 34, a third rectifying element 43, and a fourth rectifying element 44. Preferably, third switching element 33, fourth switching element 34, third rectifying element 43, and fourth rectifying element 44 are in line symmetry to first switching element 31, second switching element 32, first rectifying element 41, and second rectifying element 42. A symmetry axis SA2 of the above line symmetry extends, for example, along first surface 10A and along second direction DR2. Symmetry axis SA2 of the above line symmetry is orthogonal, for example, to symmetry axis SA1.

Each of first circuit pattern 21, second circuit pattern 22, third circuit pattern 23, fourth circuit pattern 24, and circuit pattern 20 may be in a shape in line symmetry with respect to symmetry axis SA2.

The gate electrode of each of first switching element 31 and third switching element 33 is electrically connected to first circuit pattern 21, for example, through a wiring member such as a bonding wire. The gate electrode of each of second switching element 32 and fourth switching element 34 is electrically connected to second circuit pattern 22, for example, through a wiring member such as a bonding wire. Negative electrode E2 of first switching element 31 is electrically connected to one of second portions 23B of third circuit pattern 23, for example, through a wiring member such as a bonding wire. The negative electrode of third switching element 33 is electrically connected to the other of second portions 23B of third circuit pattern 23, for example, through a wiring member such as a bonding wire. Negative electrode E2 of second switching element 32 is electrically connected to one of the second portions of fourth circuit pattern 24, for example, through a wiring member such as a bonding wire. The negative electrode of fourth switching element 34 is electrically connected to the other of the second portions of fourth circuit pattern 24, for example, through a wiring member such as a bonding wire. The positive electrode of each of third switching element 33 and fourth switching element 34 is electrically connected to circuit pattern 20. The wiring member is not limited to the bonding wire and may be any wiring member such as a ribbon or a lead.

A portion of each of first circuit pattern 21 and third circuit pattern 23 which is located on one side of third direction DR3 with respect to symmetry axis SA2 may be arranged as being aligned with first switching element 31 in second direction DR2. A portion of each of first circuit pattern 21 and third circuit pattern 23 which is located on the other side of third direction DR3 with respect to symmetry axis SA2 may be arranged as being aligned with third switching element 33 in second direction DR2.

A portion of each of second circuit pattern 22 and fourth circuit pattern 24 which is located on one side of third direction DR3 with respect to symmetry axis SA2 may be arranged as being aligned with second switching element 32 in second direction DR2. A portion of each of second circuit pattern 22 and fourth circuit pattern 24 which is located on the other side of third direction DR3 with respect to symmetry axis SA2 may be arranged as being aligned with fourth switching element 34 in second direction DR2.

As shown in FIGS. 5 and 6, signal terminal ST1 has a portion arranged as being superimposed on signal terminal ST3 in first direction DR1. Signal terminal ST2 has a portion arranged as being superimposed on signal terminal ST4 in first direction DR1. Each of signal terminal ST1, signal terminal ST3, signal terminal ST4, and signal terminal ST2 may have a portion arranged as being superimposed on one another in first direction DR1. Each of signal terminal ST1, signal terminal ST3, signal terminal ST4, and signal terminal ST2 may have a portion arranged as being superimposed on main terminal MT1 in first direction DR1.

As shown in FIG. 5, when viewed from first direction DR1, signal terminal ST1, signal terminal ST3, signal terminal ST4, and signal terminal ST2 may extend across first switching element 31 and third switching element 33 and across first rectifying element 41 and third rectifying element 43.

Main terminal MT1 may include a plurality of first internal connection portions MT1A and an external connection portion MT1B (see FIGS. 1 and 6) connected to each of the plurality of first internal connection portions MT1A and exposed to the outside of casing 100. Main terminal MT1 may further include a second internal connection portion MT1C to connect the plurality of first internal connection portions MT1A and external connection portion MT1B to each other. Second internal connection portion MT1C has, for example, a portion to connect the other ends which are opposite to one ends connected to third circuit pattern 23 in the plurality of internal connection portions MT1A and a portion that extends from the portion away from substrate 10 in first direction DR1 and is connected to external connection portion MT1B. Main terminal MT3 may be similar in configuration to main terminal MT1.

As shown in FIG. 6, each of signal terminal ST1, signal terminal ST3, signal terminal ST4, and signal terminal ST2 may have a rising portion that extends from each circuit pattern along first direction DR1 and a portion that extends from the rising portion along second direction DR2. For example, signal terminal ST3 may have a rising portion ST3A and a portion ST3B that extends from rising portion ST3A along second direction DR2. The rising portions of signal terminal ST1, signal terminal ST3, signal terminal ST4, and signal terminal ST2 are arranged at a distance from one another in second direction DR2. In signal terminal ST1, signal terminal ST3, signal terminal ST4, and signal terminal ST2, the portions that extend from the rising portions along second direction DR2 are arranged at a distance from one another in first direction DR1. In each of signal terminal ST1, signal terminal ST3, signal terminal ST4, and signal terminal ST2, the portion that extends from the rising portion along second direction DR2 may have a portion arranged as being superimposed on one another in first direction DR1. Signal terminal ST1 and signal terminal ST2 may be provided such that signal terminal ST3 and signal terminal ST4 lie therebetween in first direction DR1.

In each of signal terminal ST1, signal terminal ST3, signal terminal ST4, and signal terminal ST2, the portion that extends from the rising portion along second direction DR2 may be arranged between second internal connection portion MT1C and external connection portion MT1B of main terminal MT1 in first direction DR1. Second internal connection portion MT1C of main terminal MT1 may be arranged as being superimposed at a distance on each of signal terminal ST1, signal terminal ST3, signal terminal ST4, and signal terminal ST2 in each of first direction DR1 and third direction DR3. External connection portion MT1B may be arranged as being superimposed at a distance on each of signal terminal ST1, signal terminal ST3, signal terminal ST4, and signal terminal ST2 in first direction DR1.

Substrate 10 is fixed to casing 100 by a not-shown fixing member. The fixing member is, for example, an adhesive material. The adhesive material is, for example, a thermosetting resin-based adhesive material. A material for the adhesive material may include at least one of epoxy resin and phenol resin. The adhesive material may be an organic adhesive material. The material for the adhesive material may contain silicone rubber.

Inside casing 100, a component such as a switching element included in the bidirectional switching circuit is sealed with a not-shown sealing material. A material for the sealing material should only be any electrically insulating material. The material for the sealing material may include at least one of epoxy resin and silicone-based resin.

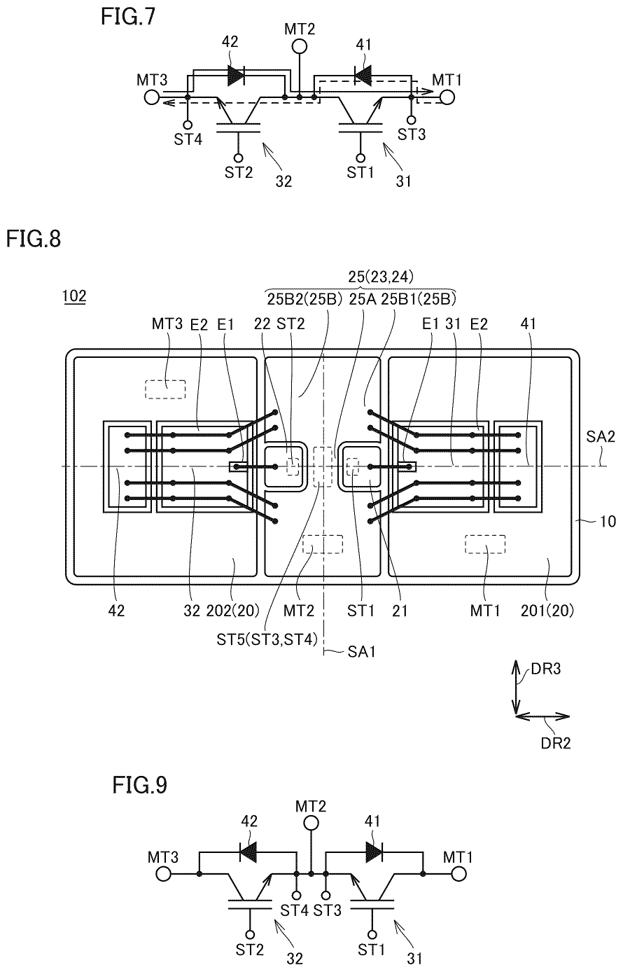

An operation of the bidirectional switching circuit of semiconductor device 101 will now be described with reference to FIG. 7. In the bidirectional switching circuit of semiconductor device 101, the first current path (a path shown with a dashed arrow in FIG. 7) extending from main terminal MT1 via first rectifying element 41 and second switching element 32 to main terminal MT3 may be formed. In addition, in the bidirectional switching circuit of semiconductor device 101, the second current path (a path shown with a solid arrow in FIG. 7) extending from main terminal MT3 via second rectifying element 42 and first switching element 31 to main terminal MT1 may be formed. In the bidirectional switching circuit, a bidirectional current path may be formed between main terminal MT1 and main terminal MT3.

An exemplary method of manufacturing semiconductor device 101 will be described below. Firstly, substrate 10 is prepared. Substrate 10 includes insulating layer 1 and conductor layer 2. Conductor layer 2 includes a plurality of conductor patterns.

Secondly, each of first switching element 31, second switching element 32, first rectifying element 41, and second rectifying element 42 is electrically joined to a corresponding conductor pattern of conductor layer 2. Joint means should only be any conductive joint material, and it is, for example, solder.

Thirdly, each of first switching element 31, second switching element 32, first rectifying element 41, and second rectifying element 42 is electrically connected to the corresponding conductor pattern of conductor layer 2 through a wiring member such as a bonding wire.

Fourthly, substrate 10 is fixed to frame portion 100A of casing 100. Though fixing means is not particularly restricted, it is, for example, a thermosetting adhesive material. At this time, lid portion 100B is yet to be fixed to frame portion 100A.

Fifthly, main terminals MT1 to MT3 and signal terminals ST1 to ST4 are electrically joined to circuit patterns 20 to 24 of conductor layer 2 of substrate 10. Though joint means is not particularly restricted, it is, for example, solder.

Sixthly, sealing with a not-shown sealing material is performed inside frame portion 100A of casing 100. The sealing material should only be any electrically insulating material, and it is, for example, thermosetting resin. In this case, the sealing material filled in frame portion 100A should only thermally be cured.

Seventhly, lid portion 100B is fixed to frame portion 100A. Semiconductor device 101 shown in FIG. 1 is thus manufactured.

A step of fixing substrate 10 to frame portion 100A of casing 100 may be performed simultaneously with a step of electrically joining main terminals MT1 to MT3 and signal terminals ST1 to ST4 to circuit patterns 20 to 24 of conductor layer 2 of substrate 10. Specifically, in one heating, a thermosetting adhesive material for fixing substrate 10 to frame portion 100A of casing 100 may thermally be cured and each terminal may be joined by solder to each conductor pattern.

### Effect of Semiconductor Device

In semiconductor device 101, when viewed from first direction DR1, gate electrode E1 of first switching element 31 and first circuit pattern 21 are in line symmetry to gate electrode E1 of second switching element 32 and second circuit pattern 22. Furthermore, when viewed from first direction DR1, third circuit pattern 23 is arranged adjacently to first circuit pattern 21. Fourth circuit pattern 24 is arranged adjacently to second circuit pattern 22.

Therefore, according to semiconductor device 101, influence by inductive magnetic field originating from the main current on each of first switching element 31 and second switching element 32 can be lessened and variation in gate drive voltage of first switching element 31 and second switching element 32 caused by inductive magnetic field can be suppressed.

Furthermore, according to semiconductor device 101, a difference in degree of influence by inductive magnetic field originating from the main current on each of first switching element 31 and second switching element 32 opposed to each other in an equivalent circuit can be reduced. Specifically, in semiconductor device 101, the difference between the degree of influence on second switching element 32 by inductive magnetic field originating from the main current when the main current flows along the dashed arrow shown in FIG. 7 and the degree of influence on first switching element 31 by inductive magnetic field originating from the main current when the main current flows along the solid arrow shown in FIG. 7 can significantly be smaller than that in the semiconductor module described in Japanese Patent Laying-Open No. 2024-13924. Consequently, according to semiconductor device 101, change in switching characteristic in accordance with an orientation of the main current can be suppressed as compared with the semiconductor module described in Japanese Patent Laying-Open No. 2024-13924.

Preferably, when viewed from first direction DR1, third circuit pattern 23 includes first portion 23A and the pair of second portions 23B. Thus, change in switching characteristic in accordance with the orientation of the main current can further be suppressed as compared with an example where third circuit pattern 23 is configured only with first portion 23A.

### Second Embodiment

A semiconductor device 102 according to a second embodiment is identical in configuration and functions and effects to semiconductor device 101 according to the first embodiment above, unless otherwise specified. Therefore, features the same as those in the first embodiment above have the same reference numerals allotted and description will not be repeated.

Semiconductor device 102 shown in FIG. 8 is a module including a bidirectional switching circuit shown in FIG. 9.

As shown in FIG. 8, also in semiconductor device 102, when viewed from first direction DR1, gate electrode E1 of first switching element 31 and first circuit pattern 21 are in line symmetry to gate electrode E1 of second switching element 32 and second circuit pattern 22 with respect to symmetry axis SA1.

In semiconductor device 102, each of third circuit pattern 23 and fourth circuit pattern 24 is provided as being integrated as a part of a fifth circuit pattern 25 (identical pattern). Fifth circuit pattern 25 is arranged adjacently to each of first circuit pattern 21 and second circuit pattern 22. Preferably, fifth circuit pattern 25 is in a shape in line symmetry with respect to symmetry axis SA1.

Fifth circuit pattern 25 includes a first portion 25A and a pair of second portions 25B. First portion 25A corresponds to first portion 23A of third circuit pattern 23 and the first portion of fourth circuit pattern 24 in semiconductor device 101. The pair of second portions 25B corresponds to the pair of second portions 23B of third circuit pattern 23 in semiconductor device 101 and the pair of second portions of fourth circuit pattern 24 in semiconductor device 101.

First portion 25A is arranged opposite to first switching element 31 with respect to first circuit pattern 21 and arranged opposite to second switching element 32 with respect to second circuit pattern 22. First portion 25A lies between first circuit pattern 21 and second circuit pattern 22.

The pair of second portions 25B extends from first portion 25A toward first switching element 31 and has a pair of third portions 25B1 arranged as being opposed to each other such that at least a part of first circuit pattern 21 lies therebetween. The pair of third portions 25B1 extends outward from opposing ends of first portion 25A in third direction DR3 and projects toward first switching element 31 relative to first portion 25A in second direction DR2.

The pair of second portions 25B extends from first portion 25A toward second switching element 32 and further has a pair of fourth portions 25B2 arranged as being opposed to each other such that at least a part of second circuit pattern 22 lies therebetween. The pair of fourth portions 25B2 extends outward from opposing ends of first portion 25A in third direction DR3 and projects toward second switching element 32 relative to first portion 25A in second direction DR2.

As shown in FIG. 8, a circuit pattern 201 electrically connected to the positive electrode of first switching element 31 is provided separately from a circuit pattern 202 electrically connected to the positive electrode of second switching element 32.

FIG. 8 shows with a dashed line, a region electrically connected to the main terminal or the signal terminal in each circuit pattern of conductor layer 2. First circuit pattern 21 includes the first connection region electrically connected to signal terminal ST1. Second circuit pattern 22 includes the second connection region electrically connected to signal terminal ST2.

Fifth circuit pattern 25 includes an eighth connection region electrically connected to each of signal terminal ST3 and signal terminal ST4. The eighth connection region is included in first portion 25A of fifth circuit pattern 25. Fifth circuit pattern 25 further includes a ninth connection region electrically connected to main terminal MT2. The ninth connection region is included in the pair of second portions 25B of fifth circuit pattern 25. The ninth connection region is arranged at a distance from the eighth connection region in third direction DR3.

Circuit pattern 201 includes a tenth connection region electrically connected to main terminal MT1. Circuit pattern 202 includes an eleventh connection region electrically connected to main terminal MT3.

The first connection region, the eighth connection region, and the second connection region are arranged as being aligned in second direction DR2. The ninth connection region, the tenth connection region, and the eleventh connection region are not arranged as being aligned with each of the first connection region, the eighth connection region, and the second connection region and first circuit pattern 21 and second circuit pattern 22 in second direction DR2. The ninth connection region, the tenth connection region, and the eleventh connection region are arranged at a distance from each of the first connection region, the eighth connection region, and the second connection region and first circuit pattern 21 and second circuit pattern 22 in third direction DR3.

First switching element 31 and first rectifying element 41 are electrically connected between main terminal MT1 and main terminal MT2. Second switching element 32 and second rectifying element 42 are electrically connected between main terminal MT2 and main terminal MT3.

Gate electrode E1 of first switching element 31 is electrically connected to signal terminal ST1. Gate electrode E1 of first switching element 31 is equal in potential to signal terminal ST1. Gate electrode E1 of second switching element 32 is electrically connected to signal terminal ST2. Gate electrode E1 of second switching element 32 is equal in potential to signal terminal ST2.

Negative electrode E2 of first switching element 31 is electrically connected to main terminal MT2 and signal terminal ST3. Negative electrode E2 of first switching element 31 is equal in potential to signal terminal ST3. Negative electrode E2 of second switching element 32 is electrically connected to main terminal MT2 and signal terminal ST4. Negative electrode E2 of second switching element 32 is equal in potential to signal terminal ST4.

The positive electrode of first switching element 31 is electrically connected to main terminal MT1. The positive electrode of second switching element 32 is electrically connected to main terminal MT3.

As shown in FIG. 9, in the bidirectional switching circuit of semiconductor device 102, a third current path leading to main terminal MT1, first switching element 31, second rectifying element 42, and main terminal MT3 or a fourth current path leading to main terminal MT3, second switching element 32. first rectifying element 41, and main terminal MT1 may be formed. In the bidirectional switching circuit, a bidirectional current path may be formed between main terminal MT1 and main terminal MT3.

In semiconductor device 102, signal terminal ST3 and signal terminal ST4 may be provided as being integrated as a single signal terminal ST5. Thus, the number of signal terminals can be smaller and manufacturing of semiconductor device 102 is easier than in an example where signal terminal ST3 and signal terminal ST4 are provided as separate members.

### Third Embodiment

A semiconductor device 103 according to a third embodiment is identical in configuration and functions and effects to semiconductor device 101 according to the first embodiment above, unless otherwise specified. Therefore, features the same as those in the first embodiment above have the same reference numerals allotted and description will not be repeated.

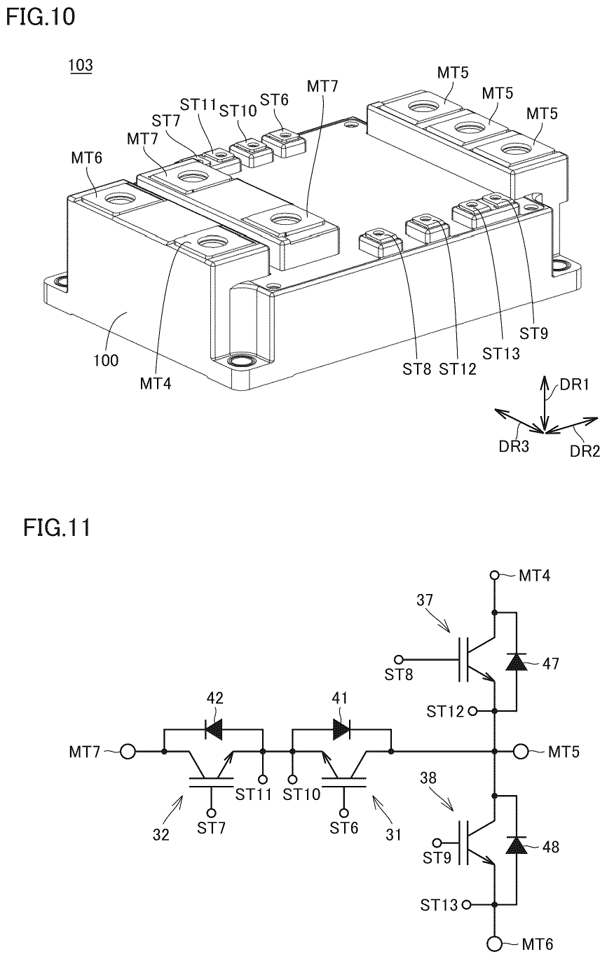

Semiconductor device 103 shown in FIG. 10 is a module including a power conversion circuit corresponding to one phase. Semiconductor device 103 is a module including a circuit shown in FIG. 11. As shown in FIG. 11, semiconductor device 103 includes a bidirectional switching circuit. Semiconductor device 103 is, for example, a module including a power conversion circuit corresponding to one phase to be included in a three-level inverter.

Semiconductor device 103 further includes main terminals MT4, MT5, MT6, and MT7 and signal terminals ST6, ST7, ST8, ST9, ST10, ST11, ST12, and ST13. Main terminals MT4, MT5, MT6, and MT7 and signal terminals ST6, ST7, ST8, ST9, ST10, ST11, ST12, and ST13 each have a portion exposed to the outside of casing 100, and are electrically connectable to external equipment.

Main terminal MT5 may be a single member having a plurality of (for example, three) external connection portions and a plurality of (for example, two) internal connection portions connected to each of the plurality of external connection portions. Main terminal MT7 may be a single member having a plurality of (for example, two) external connection portions and a plurality of (for example, two) internal connection portions connected to each of the plurality of external connection portions. Each of main terminal MT5 and main terminal MT7 may be composed of a plurality of members. Signal terminal ST10 and signal terminal ST11 may each be a single member having a plurality of (for example, two) external connection portions and a single internal connection portion connected to the plurality of external connection portions.

The circuit shown in FIG. 11 further includes a fifth switching element 37, a sixth switching element 38, a fifth rectifying element 47, and a sixth rectifying element 48, in addition to first switching element 31, second switching element 32, first rectifying element 41, and second rectifying element 42.

The gate electrode of first switching element 31 is electrically connected to signal terminal ST6. The gate electrode of second switching element 32 is electrically connected to signal terminal ST7. A gate electrode of fifth switching element 37 is electrically connected to signal terminal ST8. A gate electrode of sixth switching element 38 is electrically connected to signal terminal ST9.

The negative electrode of first switching element 31 is electrically connected to signal terminal ST10. The negative electrode of second switching element 32 is electrically connected to signal terminal ST11. A negative electrode of fifth switching element 37 is electrically connected to signal terminal ST12 and main terminal MT5. A negative electrode of sixth switching element 38 is electrically connected to signal terminal ST13 and main terminal MT6.

The positive electrode of first switching element 31 is electrically connected to main terminal MT5. The positive electrode of second switching element 32 is electrically connected to main terminal MT7. A positive electrode of fifth switching element 37 is electrically connected to main terminal MT4. A positive electrode of sixth switching element 38 is electrically connected to main terminal MT5.

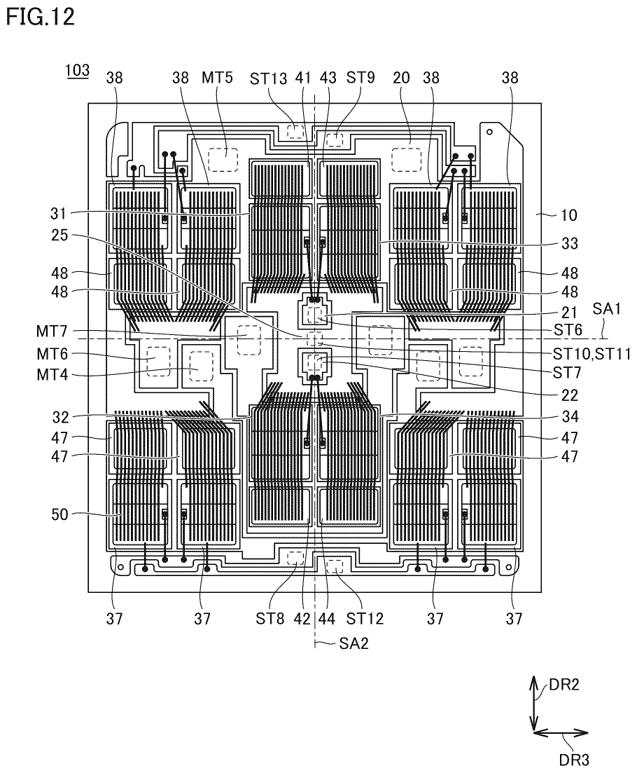

Each of main terminals MT4, MT5, MT6, and MT7 is electrically connected to a plurality of (for example, two) circuit patterns. FIG. 12 shows with a dashed line, a region electrically connected to the main terminal or the signal terminal in each circuit pattern of conductor layer 2.

As shown in FIG. 12, also in semiconductor device 103, when viewed from first direction DR1, the gate electrode of first switching element 31 and first circuit pattern 21 are in line symmetry to the gate electrode of second switching element 32 and second circuit pattern 22 with respect to symmetry axis SA1. When viewed from first direction DR1, the gate electrode of third switching element 33 and first circuit pattern 21 are in line symmetry to the gate electrode of fourth switching element 34 and second circuit pattern 22 with respect to symmetry axis SA1.

Preferably, third switching element 33, fourth switching element 34, third rectifying element 43, and fourth rectifying element 44 are in line symmetry to first switching element 31, second switching element 32, first rectifying element 41, and second rectifying element 42 with respect to symmetry axis SA2.

Preferably, in a plurality of circuit patterns included in conductor layer 2, a plurality of connection regions electrically connected to each of main terminal MT4, main terminal MT5, main terminal MT6, and main terminal MT7 and a plurality of circuit patterns including the respective connection regions are in line symmetry to each other with respect to symmetry axis SA2. For example, in a set of connection regions electrically connected to main terminal MT4 and circuit patterns including the respective connection regions, the connection region and the circuit pattern located on one side in third direction DR3 with respect to fifth circuit pattern 25 are preferably in line symmetry to the connection region and the circuit pattern located on the other side in third direction DR3 with respect to fifth circuit pattern 25.

According to such a semiconductor device 103, when semiconductor device 103 is used to configure the three-level inverter, while a parasitic inductance of the power conversion circuit is reduced, change in switching characteristics in accordance with the orientation of the main current can be suppressed.

### Additional Aspects

Various embodiments of the present disclosure are summarized as Additional Aspects.

### <Additional Aspect 1>

A semiconductor device includes

a bidirectional switching circuit,

the bidirectional switching circuit includes
a substrate having a first surface, and
a first switching element, a second switching element, a first rectifying element, and a second rectifying element that are mounted on the first surface,

the first rectifying element is connected in anti-parallel to the first switching element,

the second rectifying element is connected in anti-parallel to the second switching element,

each of the first switching element and the second switching element includes a positive electrode, a negative electrode, and a gate electrode,

the substrate includes
a first circuit pattern electrically connected to the gate electrode of the first switching element,
a second circuit pattern electrically connected to the gate electrode of the second switching element,
a third circuit pattern electrically connected to the negative electrode of the first switching element, and
a fourth circuit pattern electrically connected to the negative electrode of the second switching element,

when viewed from a first direction orthogonal to the first surface, the gate electrode of the first switching element and the first circuit pattern are in line symmetry to the gate electrode of the second switching element and the second circuit pattern, and

when viewed from the first direction, the third circuit pattern is arranged adjacently to the first circuit pattern and the fourth circuit pattern is arranged adjacently to the second circuit pattern.

### <Additional Aspect 2>

In the semiconductor device described in Additional Aspect 1,

when viewed from the first direction, the third circuit pattern includes
a first portion arranged opposite to the first switching element with respect to the first circuit pattern, and
a pair of second portions that extends from the first portion toward the first switching element, the pair of second portions being arranged as being opposed to each other such that at least a part of the first circuit pattern lies between the second portions.

### <Additional Aspect 3>

In the semiconductor device described in Additional Aspect 2,

when viewed from the first direction, the third circuit pattern is in line symmetry to the fourth circuit pattern.

### <Additional Aspect 4>

In the semiconductor device described in any one of Additional Aspects to 3,

each of the third circuit pattern and the fourth circuit pattern is provided as being integrated as a part of an identical pattern.

### <Additional Aspect 5>

In the semiconductor device described in Additional Aspect 4,

the first switching element, the first circuit pattern, the identical pattern, the second circuit pattern, and the second switching element are arranged as being aligned in a second direction along the first surface,

the semiconductor device further includes a signal terminal electrically connected to the identical pattern, and

in the identical pattern, the signal terminal is connected to a region located between the first circuit pattern and the second circuit pattern.

### <Additional Aspect 6>

In the semiconductor device described in any one of Additional Aspects to 3,

the third circuit pattern and the fourth circuit pattern are arranged at a distance from each other.

<additional Aspect 7>

In the semiconductor device described in Additional Aspect 6,

the first switching element, the first circuit pattern, the third circuit pattern, the fourth circuit pattern, the second circuit pattern, and the second switching element are arranged as being aligned in a second direction along the first surface,

the semiconductor device further includes a signal terminal electrically connected to the third circuit pattern, and

in the third circuit pattern, the signal terminal is connected to a region located between the first circuit pattern and the second circuit pattern.

### <Additional Aspect 8>

In the semiconductor device described in any one of Additional Aspects to 7,

the bidirectional switching circuit further includes a third switching element and a fourth switching element, and

when viewed from the first direction, the gate electrode of each of the first switching element and the third switching element as well as the first circuit pattern are in line symmetry to the gate electrode of each of the second switching element and the fourth switching element as well as the second circuit pattern.

<additional Aspect 9>

In the semiconductor device described in Additional Aspect 8,

the third switching element and the fourth switching element are mounted on the first surface of the substrate.

### <Additional Aspect 10>

The semiconductor device described in any one of Additional Aspects 1 to 9 includes a power conversion circuit corresponding to one phase including the bidirectional switching circuit, and further includes a casing where the power conversion circuit corresponding to the one phase is accommodated.

### <Additional Aspect 11>

In the semiconductor device described in any one of Additional Aspects 1 to 10,

a semiconductor material for at least one of the first switching element and the second switching element is a wide bandgap semiconductor.

Though embodiments of the present invention have been described, it should be understood that the embodiments disclosed herein are illustrative and non-restrictive in every respect. The scope of the present invention is defined by the terms of the claims and is intended to include any modifications within the scope and meaning equivalent to the terms of the claims.

What is claimed is:

1. A semiconductor device comprising:
a bidirectional switching circuit, wherein
the bidirectional switching circuit comprises
a substrate having a first surface, and
a first switching element, a second switching element, a first rectifying element, and a second rectifying element that are mounted on the first surface,
the first rectifying element is connected in anti-parallel to the first switching element,
the second rectifying element is connected in anti-parallel to the second switching element,
each of the first switching element and the second switching element comprises a positive electrode, a negative electrode, and a gate electrode,
the substrate comprises
a first circuit pattern electrically connected to the gate electrode of the first switching element,
a second circuit pattern electrically connected to the gate electrode of the second switching element,
a third circuit pattern electrically connected to the negative electrode of the first switching element, and
a fourth circuit pattern electrically connected to the negative electrode of the second switching element,
when viewed from a first direction orthogonal to the first surface, the gate electrode of the first switching element and the first circuit pattern are in line symmetry to the gate electrode of the second switching element and the second circuit pattern, and
when viewed from the first direction, the third circuit pattern is arranged adjacently to the first circuit pattern and the fourth circuit pattern is arranged adjacently to the second circuit pattern.

2. The semiconductor device according to claim 1, wherein
when viewed from the first direction, the third circuit pattern comprises
a first portion arranged opposite to the first switching element with respect to the first circuit pattern, and
a pair of second portions that extends from the first portion toward the first switching element, the pair of second portions being arranged as being opposed to each other such that at least a part of the first circuit pattern lies between the second portions.

3. The semiconductor device according to claim 2, wherein
when viewed from the first direction, the third circuit pattern is in line symmetry to the fourth circuit pattern.

4. The semiconductor device according to claim 1, wherein
each of the third circuit pattern and the fourth circuit pattern is provided as being integrated as a part of an identical pattern.

5. The semiconductor device according to claim 4, wherein
the first switching element, the first circuit pattern, the identical pattern, the second circuit pattern, and the second switching element are arranged as being aligned in a second direction along the first surface,
the semiconductor device further comprises a signal terminal electrically connected to the identical pattern, and
in the identical pattern, the signal terminal is connected to a region located between the first circuit pattern and the second circuit pattern.

6. The semiconductor device according to claim 1, wherein
the third circuit pattern and the fourth circuit pattern are arranged at a distance from each other.

7. The semiconductor device according to claim 6, wherein
the first switching element, the first circuit pattern, the third circuit pattern, the fourth circuit pattern, the second circuit pattern, and the second switching element are arranged as being aligned in a second direction along the first surface,
the semiconductor device further comprises a signal terminal electrically connected to the third circuit pattern, and
in the third circuit pattern, the signal terminal is connected to a region located between the first circuit pattern and the second circuit pattern.

8. The semiconductor device according to claim 1, wherein
the bidirectional switching circuit further comprises a third switching element and a fourth switching element, and
when viewed from the first direction, the gate electrode of each of the first switching element and the third switching element as well as the first circuit pattern are in line symmetry to the gate electrode of each of the second switching element and the fourth switching element as well as the second circuit pattern.

9. The semiconductor device according to claim 8, wherein
the third switching element and the fourth switching element are mounted on the first surface of the substrate.

10. The semiconductor device according to claim 1, comprising a power conversion circuit corresponding to one phase comprising the bidirectional switching circuit, and further comprising a casing where the power conversion circuit corresponding to the one phase is accommodated.

11. The semiconductor device according to claim 1, wherein
a semiconductor material for at least one of the first switching element and the second switching element is a wide bandgap semiconductor.

12. The semiconductor device according to claim 2, wherein
each of the third circuit pattern and the fourth circuit pattern is provided as being integrated as a part of an identical pattern.

13. The semiconductor device according to claim 12, wherein
the first switching element, the first circuit pattern, the identical pattern, the second circuit pattern, and the second switching element are arranged as being aligned in a second direction along the first surface,
the semiconductor device further comprises a signal terminal electrically connected to the identical pattern, and
in the identical pattern, the signal terminal is connected to a region located between the first circuit pattern and the second circuit pattern.

14. The semiconductor device according to claim 3, wherein
each of the third circuit pattern and the fourth circuit pattern is provided as being integrated as a part of an identical pattern.

15. The semiconductor device according to claim 14, wherein
the first switching element, the first circuit pattern, the identical pattern, the second circuit pattern, and the second switching element are arranged as being aligned in a second direction along the first surface,
the semiconductor device further comprises a signal terminal electrically connected to the identical pattern, and
in the identical pattern, the signal terminal is connected to a region located between the first circuit pattern and the second circuit pattern.

16. The semiconductor device according to claim 2, wherein
the third circuit pattern and the fourth circuit pattern are arranged at a distance from each other.

17. The semiconductor device according to claim 16, wherein
the first switching element, the first circuit pattern, the third circuit pattern, the fourth circuit pattern, the second circuit pattern, and the second switching element are arranged as being aligned in a second direction along the first surface,
the semiconductor device further comprises a signal terminal electrically connected to the third circuit pattern, and
in the third circuit pattern, the signal terminal is connected to a region located between the first circuit pattern and the second circuit pattern.

18. The semiconductor device according to claim 3, wherein
the third circuit pattern and the fourth circuit pattern are arranged at a distance from each other.

19. The semiconductor device according to claim 18, wherein
the first switching element, the first circuit pattern, the third circuit pattern, the fourth circuit pattern, the second circuit pattern, and the second switching element are arranged as being aligned in a second direction along the first surface,
the semiconductor device further comprises a signal terminal electrically connected to the third circuit pattern, and
in the third circuit pattern, the signal terminal is connected to a region located between the first circuit pattern and the second circuit pattern.

20. The semiconductor device according to claim 2, wherein
the bidirectional switching circuit further comprises a third switching element and a fourth switching element, and
when viewed from the first direction, the gate electrode of each of the first switching element and the third switching element as well as the first circuit pattern are in line symmetry to the gate electrode of each of the second switching element and the fourth switching element as well as the second circuit pattern.
